(19) United States
(12) Patent Application Publication
(10) Pub. No.: US 2004/0224148 A1
(43) Pub. Date: Nov. 11, 2004

(54) Anisotropically conductive sheet

(76) Inventor: Hitoshi Matsunaga, Ebina-shi (JP)

Correspondence Address: RATNERPRESTIA, P.O. BOX 1596, WILMINGTON, DE, 19899, US

(21) Appl. No.: 10/840,522

(22) Filed: May 6, 2004

(30) Foreign Application Priority Data
May 8, 2003 (JP) 2003-129773
Dec. 24, 2003 (JP) 2003-427504

(51) Int. Cl. H01L 21/44; H01L 21/48; H01L 21/50; B32B 1/00

(52) U.S. Cl. 428/332

(57) ABSTRACT

An anisotropic conductivity sheet (10) comprising an insulating sheet (11) and number of conductive bodies is provided. The insulating sheet (11) is composed of a heat resistant fuloro-elastomer and has a number of through-holes (12). Each of the conductive bodies is a metal wire loop (13) formed to elliptic shape. They are inserted vertically into each of the through-holes (12) so that long axe of each elliptic loop (13) extends in the thickness direction of the insulating sheet (11). Both surfaces of the insulating sheet (11) are preferably coated or laminated with thin layers (14, 15) of heat-resistant engineering plastics. The anisotropic conductivity sheet (10) is suitable to use for electrical test of a semiconductor devise (16), such as IC. A signal waveform-rectifying sheet (20) is preferably arranged on the anisotropic conductivity sheet (10). The signal waveform-rectifying sheet (20) has though-holes (22) in which electrical components for rectifying signals and currents, such as resistors (23A), LEDs (23B), LR circuits (23C) and capacitors (23D), are filled up.

### CROSS REFERENCE TO RELATED CASES

This application is based on Japanese patent applications Ser. No. 2003-129773 filed on May 8, 2003 and Ser. No. 2003-427504 filed on Dec. 24, 2003, the contents of which are incorporated hereinto by reference.

### BACKGROUND OF INVENTION

1. Field of the Invention

The present invention relates to a novel anisotropically conductive sheet, particularly, relates to a novel anisotropically conductive sheet useful for a test to inspect electrical properties of semiconductor devises such as semiconductor integrated circuits, simply called as ‘IC’ hereinafter, and relates to an apparatus for testing the semiconductor devices including a novel electrical interface using the anisotropically conductive sheet.

2. Description of the Related Art

Up until now, there have been proposed a wide variety of conventional electrically conductive sheets or films having an electrical conductivity only in thickness direction thereof, which is applied to an electrical test of a semiconductor devise.

In order to test electrical properties of a semiconductor device such as IC, terminals of the semiconductor device shall be connected electrically with electrodes on a circuit of tester. However, semiconductor devices have various own constructions each by each and it is necessary to use appropriate means for assuring electrical connections between terminals of the semiconductor device and electrodes on a circuit of tester.

As one of such means, an anisotropically conductive film is proposed in Japanese published patent application Kokai H07-140480A. The anisotropically conductive film comprises a composition in which conductive fine particles are dispersed in an insulating adhesive material.

At test stage of a semiconductor device, the anisotropically conductive film is laid between terminals of the semiconductor device and electrodes on circuit of a tester and then compresses the semiconductor device toward the circuit of tester through the anisotropically conductive film to connect electrically the both.

Most of recently developed semiconductor devices, for example IC, are higher integrated and, therefore, the semiconductor devices becomes to high temperature, for example above 100° C., at test stage due to electric currents given to the semiconductor devices. In order to meet such high temperature, an anisotropically conductive film made of heat resistant materials is proposed. However, vibrations of the film take place by an outside pressure and static electricity is generated on the film during the test procedure. These problems cause difficulties to obtain exact test results.

Furthermore, when a semiconductor device to be inspected is pressed down to a circuit board of tester through the anisotropically conductive film, the film often adheres to the semiconductor device and/or a circuit board of the tester, for a vacuum space is formed between the semiconductor device and the circuit board by such pressing down. Thus, the film is occasionally damaged when the semiconductor device and the films are removed respectively from the circuit board after the test is finished.

For avoiding such drawbacks, an anisotropically conductive sheet has been suggested in Japanese published patent application Kokai H09-35789A. The anisotropically conductive sheet comprises an insulating material composed of silicone rubber and an electrically conductive material existing in the insulating material.

As the anisotropically conductive sheet has an adequate thickness, any vibration or adherence of the sheet does not appear. However, an oily material oozes out from the insulating material during the test, because the insulating material of the conductive sheet is made of silicone rubber. The oily material may pollute the semiconductor device and the circuit board of tester and it may bring troubles on a normal test. Since the oozing out of the oily material is increased at higher temperature, this anisotropically conductive sheet is unsuitable to apply for testing highly integrated IC, which rises in temperature during the test.

Furthermore, as the above anisotropically conductive sheet comprises a conventional conductive material, such as a conductive material having a ball-like shape, the ball-like conductive material may be deformed and damaged when a semiconductor device is pressed down toward the circuit board of tester through the anisotropically conductive sheet.

### SUMMARY OF THE INVENTION

It is, therefore, an object of the present invention is to provide an improved anisotropically conductive sheet which is able to establish reliable electrical connection between terminals of a semiconductor device, such as IC, with electrodes on a circuit board of tester without drawbacks mentioned above, and to obtain accurate test results, even if a temperature of the semiconductor device rises during the test.

It is another object of the present invention to provide a novel an apparatus for testing a semiconductor device including a novel electrical interface using the anisotropically conductive sheet.

According to the present invention, there is provided that an anisotropically conductive sheet comprising an insulating sheet composed of a heat resistant fluoro-elastomer which has a plurality of through-holes passing through the insulating sheet in thickness direction thereof and a plurality of loops having elliptic shape or the like made of electrically conductive wires, each of the elliptic loops being held in each of the through-holes of the insulating sheet so that long axes of the elliptic loops extend in thickness direction of the insulating sheet, and each of the elliptic loops contacting with inner surface of each of the through-holes at both sides of the elliptic loops and at ends of looped wires to hold the elliptic loops in each of the through-holes.

The anisotropically conductive sheet has through-holes passing through the insulating sheet and in each of the through-holes a loop of a conductive wire shaped as ellipse or the like is held so that long axe of the elliptic loop extends in thickness direction of the insulating sheet whereby connect electrically terminals of a semiconductor device with electrodes on an electrical circuit of tester.

The anisotropically conductive sheet of the present invention is laid between electrically terminals of a semiconductor device under test and electrodes of the circuit of tester, to establish electrical connections between the both.

According to the present invention, there is also provided that an apparatus for testing or inspecting electrically a semiconductor devise comprising the anisotropically conductive sheet mentioned above and a tester having an electrical circuit for testing semiconductor devices. The apparatus may include a novel electrical interface between terminals of a semiconductor device under test and corresponding electrodes of the circuit of tester. The electrical interface comprises the above-mentioned anisotropically conductive sheet and a signal waveform-rectifying sheet for adjusting profiles of signal waves and/or electrical currents inputting into the semiconductor devise and outputting from the same. The signal waveform-rectifying sheet is made of an insulating sheet composed of a heat resistant elastic material having a plurality of through-holes extending in thickness direction thereof and at least one waveform-rectifying component is arranged in the through-holes.

### BRIEF DESCRIPTION OF THE DRAWINNGS

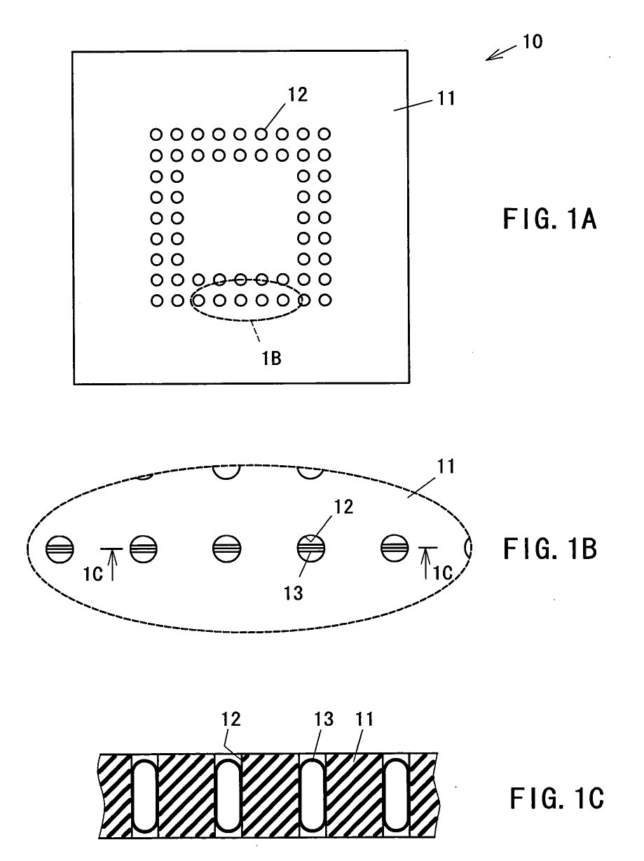

FIGS. 1A, 1B and 1C illustrate a construction of an anisotropically conductive sheet, which is an embodiment of the present invention. FIG. 1A is a plane view of the whole anisotropically conductive sheet. FIG. 1B is an enlarged plane view of a part of the anisotropically conductive sheet. FIG. 1C is an enlarged cross sectional view of the part of the anisotropically conductive sheet.

FIG. 2 is a side view of an exemplary elliptic loop of electrical conductive wire, which constitutes an electrical conductive part of the anisotropically conductive sheet of the present invention.

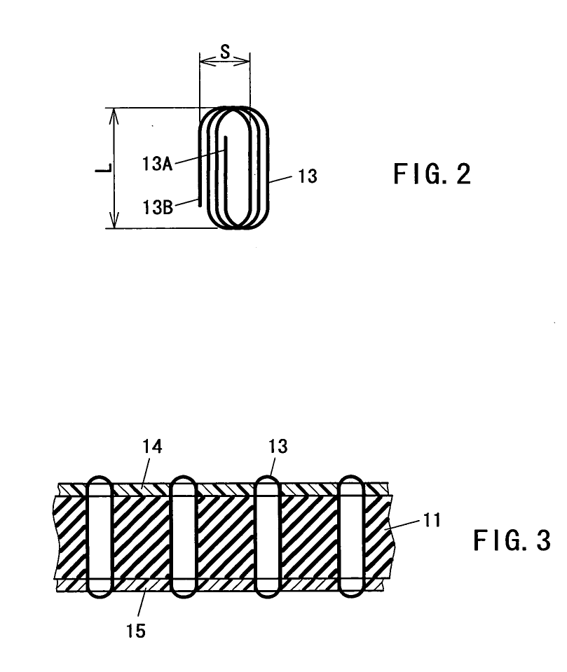

FIG. 3 is a cross sectional view of another anisotropically conductive sheet, which is a preferable embodiment of the present invention.

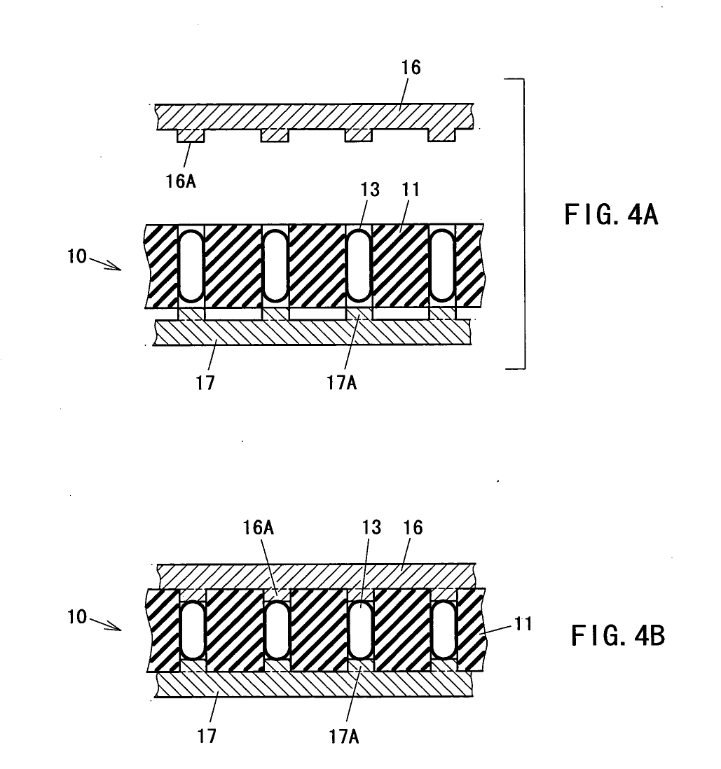

FIGS. 4A and 4B illustrate embodiments of an apparatus for testing or inspecting IC using the anisotropically conductive sheet. FIG. 4A is a cross sectional views of an arrangement of IC to be tested and the anisotropically conductive sheet at preparing stage for test and FIG. 4B is a cross sectional views of the arrangement at test stage.

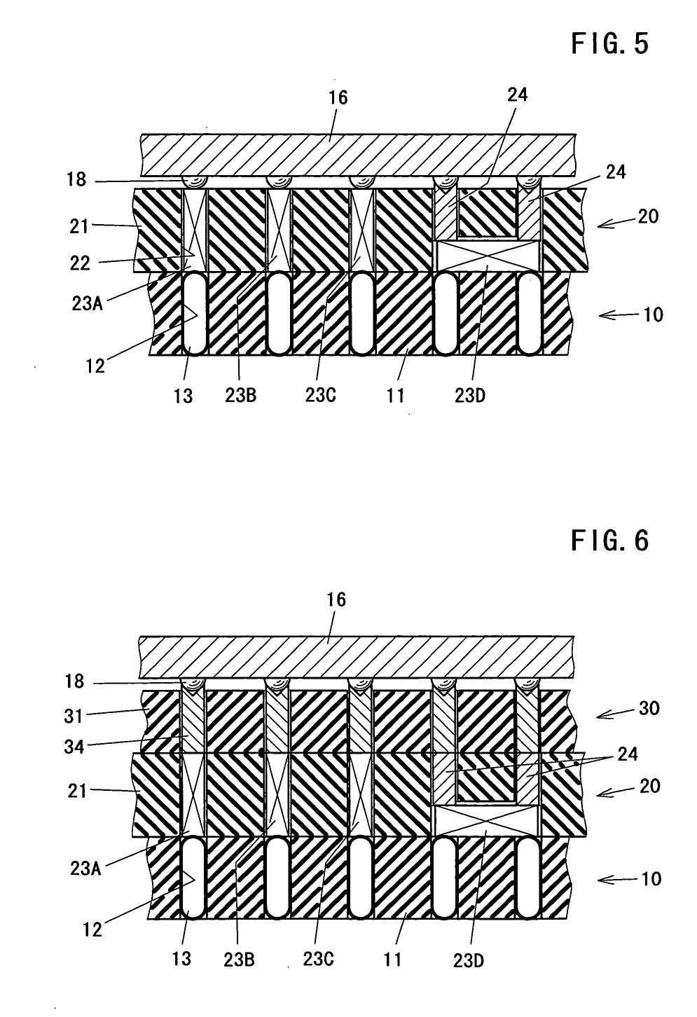

FIG. 5 is a cross sectional view of an assembly including the electrical interface according to the present invention, in which a signal waveform-rectifying sheet is arranged between the IC and the anisotropically conductive sheet.

FIG. 6 is a cross sectional view of an another assembly including the electrical interface according to the present invention, in which a contact sheet is laid additionally between the IC and the signal waveform-rectifying sheet.

### DETAILED DESCRIPTION OF THE PREFERRED EMBODIMENTS

The present invention will hereinafter be described in details with reference to the accompanying drawings.

FIG. 1A shows a plan view of an exemplary anisotropically conductive sheet according to the present invention and FIG. 1B shows an enlarged plane view of a part of this anisotropically conductive sheet. FIG. 1C shows 1C-1C cross-section of the part shown in FIG. 1B.

As seen from these drawings, an anisotropically conductive sheet 10 according to the present invention comprises basically an insulating sheet 11 and elliptical loops 13 of conductive wires as electrically conductive bodies arranged in the insulating sheet 11.

The insulating sheet 11 constituting the anisotropically conductive sheet 10 of the present invention is composed of a heat-resistant fluoro-elasomer, which is an insulating polymeric material having an appropriate elasticity and excellent thermal stability. As desirable examples of the fluoro-elastomers, ‘Viton’™ (a product of DuPont Dow Elastomers), ‘Dyneon’™ (a product of 3M), ‘AFLAS’™ (a product of Asahi-Glass company, Ltd.) and ‘DAI-EL’™ (a product of Daikin Industries, Ltd.) are indicated.

There is no oozing-out of materials from the insulating sheet 11 even if it is used under high temperature environments, because the fluoro-elastomer has an excellent heat-resistance. As compared with this, insulating sheets made of silicone rubber constituting conventional anisotropically conductive sheets often ooze out oily materials at high temperature.

The insulating sheet 11 has preferably a thickness of 0.15 mm to 1.2 mm, more preferably a thickness of 0.2 mm to 1.0 mm.

As illustrated in the drawings, the insulating sheet 11 has a plurality of through-holes 12 passing through the insulating sheet 11 from front surface to back surface thereof. Each of the through-holes 12 preferably has circular cross section to form a small cylindrical space through the insulating sheet 11. Although the cross section of through-holes 12 illustrated in FIGS. 1A and 1B is circle, the cross section of through-holes 12 may be the other shapes, such as ellipse, square, pentagon, hexagon or octagon.

A preferable diameter of each through-hole is in a range of about 45 to 65% of the thickness of the insulating sheet 11, namely a range of about 0.067 mm to about 0.78 mm. A length of each through-hole 12 generally depends upon the thickness of the insulating sheet. As mentioned above, a preferable thickness of the insulating sheet 11 is in a range of 0.15 mm to 1.2 mm and therefore preferable length of the through-hole 12 is also in a range of 0.15 mm to 1.2 mm.

Positions of each through-hole 12 on the insulating sheet 11 are arranged depending on a layout of terminals of IC to be inspected. For example, through-holes 12 are lined up as shown in FIG. 1A so as to correspond to a layout of the terminals of IC.

In the anisotropically conductive sheet 10, each elliptic loop 13 of a conductive wire is inserted virtually into each through-hole 12 of the insulating sheet 11 one by one as indicated in FIG. 1C. Each elliptic loop 13 is held in each through-hole 12, so that the long axis of the ellipse extends in thickness direction of the insulating sheet 11.

Thus, each of the elliptic loops 13 of wire is held in each of the through-holes 12 so that long axis of the elliptic loops 13 are extending longitude direction of the through-hole 12, and the elliptically looped wire in the through-hole acts as an electrically conductive body of the anisotropically conductive sheet to connect electrically terminals of IC with electrodes of a circuit board of tester.

Each elliptic loop 13 is made of a thin wire of an electrically conductive metal, preferably a conductive metal having low hardness. Among them, aluminum, cupper, silver and alloys thereof are most preferable. However, ions including steel, iron alloys and other conductive metals are also may be used.

The diameter of the thin wire is preferably 60 μm to 200 μm. In the case that the metal wire is too thin, it is difficult to form elliptic loops thereby and if the wire is too thick, it is not easy to insert an elliptic loop of the wire into the through-hole.

A preferable example of an elliptic loop 13 of a conductive wire is shown in FIG. 2. The elliptic loop 13 is desirably prepared by winding or coiling the metal wire for plural turns, particularly three to ten turns as illustrated in FIG. 2. The multi-turned loop 13 is able to have a broad contacting area with terminals of IC and it brings more stable electrical conductivities at test stage. As the result, accuracy and reliability of the test can be enhanced. Therefore, although each elliptic loop of the metal wire is illustrated as a single line in the drawings other than FIG. 2, it should be understood that the single line might indicate the loop of a bundle of metal wires.

A size of the elliptic loops 13 of wire should be chosen depending upon the size of the through-holes 12. In general, it is preferable that each of the elliptic loops 13 has a long diameter (L) of 0.2 mm to 1.3 mm and a short diameter (S) of 0.05 mm to 0.6 mm. More preferably, the long diameter (L) is slightly larger than the thickness of the insulating sheet 11 or equal to the same.

Both sides of the each ellipse loop contact tightly with inner wall of the through-hole 12 and further each of the head and tail ends 13A and 13B of the looped wire contact strongly with inner wall of the through-hole 12, whereby each loop 13 is hold and fixed firmly in each through-hole 12. However, top and bottom portions of the ellipse may project out slightly from upper and lower openings of the through-hole 12 of the insulating sheet 11, respectively.

Although the elliptically looped wire 13 illustrated in FIG. 1C exists entirely in the through-hole 12, the top and bottom parts of elliptic loop 13 may project out slightly from upper and lower openings of the through-hole 12, as described below.

FIG. 3 illustrates an example of more preferable anisotropically conductive sheet according to the present invention. The anisotropically conductive sheet 10 has heat resistant thin layers 14 and 15 of engineering plastics on both of front and back surfaces of the insulating sheet 11, respectively.

The thin layers 14 and 15 are composed of one or more heat resistant engineering plastics, such as polyimide and/or polyetheretherketon (PEEK). The engineering plastics layers 14 and 15 cover generally all surfaces area of the insulating sheet 11 excepting openings of the through-holes. Each of the layers 16 and 17 of engineering plastics has a thickness of 0.005 mm to 0.1 mm, preferably 0.01 mm to 0.1 mm.

The thin layers 14 and 15 may be formed by coating of a solution, dispersion or melt of the engineering plastics or by laminating of a thin film composed of the engineering plastics on the both surface of the insulating sheet 11.

In this embodiment, top and bottom parts of the elliptic loop 13 are projecting out slightly from upper and lower openings of the through-hole 12, as indicated in FIG. 3. Although whole elliptically looped wires 13 are held in the through-hole 12 at the anisotropically conductive sheet 10 shown in FIG. 1C, it is preferable in most cases that only top and bottom parts of the elliptic loop 13 project out slightly from upper and lower ends of the through-hole 12, as indicated in FIG. 3.

The anisotropically conductive sheet 10 having a mufti-layer structure, as illustrated in FIG. 3, is excellent in mechanical property and dimension stability of whole structure as it is reinforced by engineering plastics layers and, further, in accuracy of positioning of the through-holes. In addition to the above, damages of elliptically looped wire 13 during test become fewer and, therefore, the certainty of test and life of the anisotropically conductive sheet 10 are remarkably improved.

An embodiment of applying the anisotropically conductive sheet 10 for electrical test of a semiconductor device, such as IC, is explained hereinafter, referring to FIGS. 4A and 4B.

FIG. 4A shows a simplified cross sectional view of a preparing stage of the electrical test of IC 16. The IC 16 having a number of terminals 16A is illustrated in upper potion of the drawing, and an anisotropically conductive sheet 10 of this invention and electrode pads 17A of a circuit board 17 of a tester is also illustrated in lower portion of the drawing, where the anisotropically conductive sheet 10 is put just on the circuit board 17 of tester. The electrode pads 17A of the upper surface of the circuit board 17 are arranged in a pattern of corresponding to a pattern of terminals 16A of IC 16.

FIG. 4B shows a simplified cross sectional view of a testing stage. IC 16 is put on the anisotropically conductive sheet laid over the circuit board 17 of the tester, and then IC 16 is pressed down toward the circuit board 17, so that terminals 16A of the IC 16 and electrode pads 17A in the circuit board 17 are electrically connected by the elliptically looped wires 13 of an anisotropically conductive sheet 10, whereby an electrical connection between the IC terminals 16A and the electrode pads 17A is securely established. At the test stage, an electric current is conducted into whole components to inspect electrical properties of IC 16. During the current test, a highly integrated IC 16 often rises in temperature and, however, any material oozed from the anisotropically conductive sheet 10 is not observed, even at high temperature.

As the insulating sheet 11 of the anisotropically conductive sheet 10 is composed of a heat-resistant elastomer and any oily materials do not appear, even if the test is undertaken at elevated temperature, the electrical connection between terminals 16A of high-integrated IC 16 and electrode 17Aa of the electrical circuit 17 is assured during whole test stages using the anisotropically conductive sheet 10.

Since elliptic loops 13 of conductive wire in the through-holes 12 have elasticity against a vertical pressure, the elliptic loops 13 can absorb unevenness and projections of IC terminals 16A when IC 16 is pressed down. As the results, an accurate electrical connection between IC terminals 16A with electrodes 17A of the electrical circuit 17 is established by using the anisotropically conducive sheet 10 of the present invention. Furthermore, damages of IC terminals 16A and electrodes 17A of the electrical circuit 17 can be minimized, for the elliptically looped wires 13 are possible to transform temporally to avoid damaging the terminals.

In addition to the above, since the elliptically looped wires 13 are held vertically in through-holes 12, it is possible to shorten diameter of the through-holes 12 and to minimize spaces between neighboring through-holes, and therefore the through-holes 12 can be arranged at fine intervals. Accordingly, the anisotropically conductive sheet 10 of this invention is suitable to use for tests of IC 16 on which many terminals 16A are arranged tightly. That is, the vertical arrangement of the wire loops 13 in the through-holes 12 makes easy to minimize area where the conductive materials occupy on the insulating sheet 11, comparing with ball-like conductive materials,

Furthermore, fine air paths are formed naturally between inner walls of the through-holes 12 and the elliptic loop 13 of wires, where air can pass through when the IC is pressed down toward the anisotropically conductive sheet 10. The fine air path make possible to prevent from sticking of IC 16 to the anisotropically conductive sheet 10 and become easy to remove the IC 16 from the anisotropically conductive sheet 10, after the test is completed.

The anisotropically conductive sheet according to the invention can be prepared for lower cost than conventional one. This is important from economical viewpoint.

As understood from the above, an anisotropically conductive sheet in accordance with this invention has many advantageous effects. Using this sheet, steady tests of semiconductor devices can be carried out without any damages of the semiconductor devices and circuits of testers and problems of test under high temperature, and thus reliable test results can be obtained.

An apparatus for testing or inspecting a semiconductor device, such as IC, can be constructed by arranging the anisotropically conductive sheet described above on electrodes of the circuit board of tester. The anisotropically conductive sheet is laid over electrodes of the circuit board and then a semiconductor device to be inspected is put on it to perform the test, as illustrated in FIGS. 4A and 4B. And then electric currents are conducted into the construction to start the test.

However, it is preferable that test is performed under the arrangement of another connecting sheet (not shown in the drawings) between IC and the anisotropically conductive sheet of the present invention. A preferred example of such connecting sheet developed by Hitoshi Matsunaga is disclosed in Japanese published patent application Kokai 2003-149291A.

As intensity and voltage of electrical currents inputted into IC terminals from power lines and base lines are sometimes unstable and imbalanced and further signals furnished from IC terminals to the tester include turbulences in their waveforms and contain various kinds of noises. However, these problems can be solved by laying a novel sheet for adjusting signal waveforms, namely a signal waveform-rectifying sheet, on the anisotropically conductive sheet.

In preferable test procedures, therefore, the signal waveform-rectifying sheet is laid between the IC terminals 16A and the anisotropically conductive sheet 10 in order to improve accuracy of the test.

FIG. 5 shows an example of an electrical interface using the signal waveform-rectifying sheet 20. The signal waveform-rectifying sheet 20 comprises a substrate sheet 21 made of electrically insulating elastic material, such as a heat resistant fluoro-elastomer, and the substrate sheet 21 has a plurality of through-holes 22 extending in its thickness direction. Each of the through-holes 22 is arranged in the position respectively corresponding to the though-holes 12 of the anisotropically conductive sheet 10 and each of terminals of IC 16. Into each of the though-holes 22, an electrical component is inserted and fixed therein, by which the waveforms of signals and/or currents into or from IC are adjusted and stabilized.

The electrical component, namely a signal waveform-rectifying component, inserted into each through-hole 22 is selected depending upon functions of the corresponding terminals of IC 16. For example, as to the through-holes corresponding to signal lines, the component is selected from a resistor 23A; LED (light emitting diodes) 23B and LR circuit 23C, i.e., a circuit containing an inductor and a resistor. In the other hand, into the through-holes corresponding to power line or base line, a capacitor (condenser) 23D is selected as the electrical component. These signal waveform-rectifying components have functions to adjust intensities of electrical currents inputted to terminals of IC 16 and reduce noises in signals outputted from the terminals.

As to a through-hole 22 not necessary to adjust electrical currents or signals, a conductive piece 24 consisting of a conductive metal, such as a BoCu or carbon steel, is inserted to form a normal electrical path.

The thickness of the insulating sheet 21 has to chosen depending on the sizes of the component inserted into the though-holes 22. However, it is generally preferable that the sheet 21 has a thickness of 0.5 mm to 1.0 mm and each of the through-holes 22 has an inner diameter of 0.3 mm to 0.6 mm. Cross section of each through-hole 22 is not limited to only a circle but also a squire and other polygonal shape are available. In case that the electrical component has cylindrical shape or the like, the through-hole having a circular cross section is preferable.

As illustrated in FIG. 5, each of a resistor 23A, LED 23B and LR circuit 23C is generally inserted into the through-hole 22 vertically. However, a flat capacitor 23D may exist in the insulating sheet 21 as extending to two or more through-holes 22. In through-holes having the capacitor 23D, supplemental conductive metal pieces 24 may be inserted just on the capacitor 23D to connect in series so as to fill up conductive path in the through-hole 22.

The signal waveform-rectifying sheet 20 mentioned above is effective to adjust and average the electrical current from terminals of IC 16 to the circuit board 17 of tester and to reduce noises of signals from the respective terminals. Thus, electrical currents or signals conducted to the electrodes of the circuit board of tester through the signal waveform-rectifying sheet 20 have most appropriate values and profiles and noises are remarkably reduced.

In the case that the terminals of IC 16 under test are formed as ball-like or semi-ball like bumps 18 such as a solder ball indicated in FIGS. 5 and 6, the bumps 18 are readily deformed and damaged by pressing down thereof onto the electrical component of the signal waveform-rectifying sheet 20 at test stage. In order to solve such problem, it is recommended to arrange additionally a contact sheet 30 just on the signal waveform-rectifying sheet 20 as illustrated in FIG. 6.

The contact sheet 30 comprises an insulating substrate sheet 31 made of a heat resistant elastic material such as the fluoro-elastomer having a plurality of through-holes and a contact metal part 34 made of conductive metal, such as BoCu or carbon steel, are inserted and fixed in each of the through-holes. In a desirable embodiment, a top end of each contact metal part 34 is formed into a split-crown shape having at least two, preferably three or four, projections and a hemispherical or cylindrical recess in the central portion. The depth of the recess is deep enough for preventing contact with lower tip of the bump 18. An example of the contact metal part 34 having a shape of split-crown is disclosed in Japanese published patent application Kokai 2003-43104A. Each of the bumps 18 of IC 16 is brought into contact with the top end of the contact metal part 34. The bumps 18 are supported and connected at their side with the projections in top end of the contact metal part 34 as shown in FIG. 6. Thus, the tip of bump 18 does not contact directly with any electrical component and therefore any deformation or damaging of the tip of bump 18 can be prevented.

The present invention has been described in detail with respect to various embodiments, and it will now be apparent from the foregoing to those skilled in the art that changes and modifications may be made without departing from the invention in its broader aspects, and it is the intention, therefore, in the appended claims to cover all such changes and modifications as fall within the true spirit of the invention.

1. (Cancelled).

2. An anisotropically conductive sheet as set forth in claim 20, wherein each of said through-holes provided in said insulating sheet has circular cross section.

3. An anisotropically conductive sheet as set forth in claim 2, wherein said circular holes have a diameter of 45 to 65% of said thickness of said insulating sheet.

4. An anisotropically conductive sheet as set forth in claim 20, wherein each of said through-holes provided in said insulating sheet has a square cross section.

5. An anisotropically conductive sheet as set forth in claim 20, wherein said insulating sheet has a thickness of 0.15 to 1.2 mm.

6. An anisotropically conductive sheet as set forth in claim 20, wherein said generally elliptic loops are made of a conductive metal wire composed of aluminum, gold, copper, iron or an alloy thereof.

7. An anisotropically conductive sheet as set forth in claim 6, wherein said metal wire has a diameter of 60 μm to 200 μm.

8. An anisotropically conductive sheet as set forth in claim 6, wherein said generally elliptic loops are each formed by winding a conductive metal wire for three to ten turns.

9. An anisotropically conductive sheet as set forth in claim 6, in which a top and a bottom portion of said generally elliptic loops project out slightly from an upper and a lower ends of at least one of said plurality of through-holes of said insulating sheet.

10. An anisotropically conductive sheet as set forth in claim 20, further comprising:
heat resistant thin layers made of an engineering plastic on both of an upper and a lower surface of said insulating sheet respectively.

11. An anisotropically conductive sheet as set forth in claim 10, in which each of said heat resistant thin layers has a thickness of 0.005 mm to 0.1 mm.

12. An anisotropically conductive sheet as set forth in claim 10 wherein said layers are composed of polyimide or polyetherether ketone.

13. (Cancelled).

14. (Cancelled).

15. An electrical interface as set forth in claim 22, wherein at least one of said through holes in said signal waveform rectifying sheet connects to a signal input in said semiconductor device and wherein at least one other of said through holes in said signal waveform rectifying sheet connects to a power or base line input in said semiconductor device and wherein said signal waveform rectifying component in said through hole corresponding to said signal line of said semiconductor device is an electrical component selected from a resistor, LED, and LR circuit and said signal waveform rectifying component in said through hole corresponding to said base line or power line of said semiconductor device is a capacitor.

16. An electrical interface as set forth in claim 22, further comprising:
a contact sheet for connecting electrically terminals of said semiconductor device under test with said waveform rectifying components in said signal waveform rectifying sheet.

17. An electrical interface as set forth in claim 16, in which said contact sheet comprises an insulating sheet having through-holes and a contact metal part made of a conductive metal arranged in each of the through-holes, whereby said terminals of the semiconductor device under testing are connected with said signal waveform-rectifying component in said signal waveform-rectifying sheet.

18. An electrical interface set forth in claim 17, in which said terminals of the semiconductor device under testing are formed as ball like or semi-ball bumps.

19. An electrical interface set forth in claim 18, in which a top end of said contact metal part is formed as a split-crown shape having at least two projections and a hemispherical or cylindrical recess in central portion thereof, so that said bumps are supported and contacted with the projections of said contact metal part.

20. An anisotropically conductive sheet comprising:
(a) an insulating sheet having a thickness said insulating sheet comprising a heat resistant fluoro-elastomer and a plurality of through holes extending through said sheet thickness, said through holes having an axis extending the thickness of said sheet, and an inner surface;
(b) a plurality of electrically conductive wire loops each of said loops having a generally elliptical shape comprising a long and a short axis and two wire ends, wherein
said wire loops are inserted in said plurality of through holes respectively with said long axis generally parallel to said hole axis, and wherein
said wire loops and said wire ends are in pressed contact with said inner walls of said through holes to hold said wire loops in said holes.

21. An apparatus for testing a semiconductor device comprising an anisotropically conductive sheet and an electrical circuit tester wherein said anisotropically conductive sheet is adapted to be placed between said semiconductor device and said electrical circuit tester to provide electrical connections between terminals on said semiconductor device and electrodes on said circuit tester, said anisotropically conducting sheet comprising:
(a) an insulating sheet having a thickness said insulating sheet comprising a heat resistant fluoro-elastomer and a plurality of through holes extending through said sheet thickness, said through holes having an axis extending the thickness of said sheet, and an inner surface;
(b) a plurality of electrically conductive wire loops each of said loops having a generally elliptical shape comprising a long and a short axis and two wire ends, wherein
said wire loops are inserted in said plurality of through holes respectively with said long axis generally parallel to said hole axis, and wherein
said wire loops and said wire ends are in pressed contact with said inner walls of said through holes to hold said wire loops in said holes.

22. An electrical interface for connecting terminals of a semiconductor device and corresponding electrodes of a tester for testing said semiconductor device, said interface comprising an anisotropically conductive sheet and a signal waveform-rectifying sheet for adjusting profiles of signal waves or electrical currents inputting into and/or outputting from said semiconductor device, wherein:
said anisotropically conductive sheet comprises:
(a) an insulating sheet having a thickness said insulating sheet comprising a heat resistant fluoro-elastomer and a plurality of through holes extending through said sheet thickness, said through holes having an axis extending the thickness of said sheet, and an inner surface;
(b) a plurality of electrically conductive wire loops each of said loops having a generally elliptical shape comprising a long and a short axis and two wire ends, wherein
said wire loops are inserted in said plurality of through holes respectively with said long axis generally parallel to said hole axis, and wherein
said wire loops and said wire ends are in pressed contact with said inner walls of said through holes to hold said wire loops in said holes; and
said signal waveform-rectifying sheet comprises:
an heat resistant insulating sheet comprising an elastomer and having a thickness said heat resistant insulating sheet further comprising a plurality of through-holes extending through said heat resistant insulating sheet thickness, and
at least one signal waveform rectifying component arranged in at least one of said through-holes in said heat resistant insulating sheet.
